(19) United States
(12) Patent Application Publication
(10) Pub. No.: US 2025/0098370 A1
(43) Pub. Date: Mar. 20, 2025

(54) DISPLAY DEVICE

(71) Applicant: LG DISPLAY CO., LTD., Seoul (KR)

(72) Inventors: YoungIn JANG, Seoul (KR); KwangSu LIM, Seoul (KR); Junhyeok LEE, Seoul (KR); HyunGon KIM, Seoul (KR)

(73) Assignee: LG DISPLAY CO., LTD., Seoul (KR)

(21) Appl. No.: 18/788,349

(22) Filed: Jul. 30, 2024

(30) Foreign Application Priority Data
Sep. 15, 2023 (KR) 10-2023-0123205

(51) Int. Cl. H01L 33/24; H01L 25/16; H01L 33/62

(52) U.S. Cl. CPC H10H 20/821; H01L 25/167; H10H 20/857

(57) ABSTRACT

A display device includes a substrate on which a plurality of subpixels is defined, and a plurality of light-emitting elements respectively disposed in the plurality of subpixels. Each of the plurality of light-emitting elements includes a first semiconductor layer, a light-emitting layer on the first semiconductor layer, and a second semiconductor layer on the light-emitting layer. The first semiconductor layer includes a first part having a flat top surface, and a second part protruding upward from the first part and being in direct contact with a bottom surface of the light-emitting layer. An area of a top surface of the second semiconductor layer is larger than an area of a bottom surface of the second semiconductor layer.

### CROSS-REFERENCE TO RELATED APPLICATION

This application claims the priority of Korean Patent Application No. 10-2023-0123205 filed on Sep. 15, 2023, which is hereby incorporated by reference in its entirety.

### BACKGROUND

### Field of the Disclosure

The present disclosure relates to a display device, and more particularly, to a display device capable of suppressing a short-circuit defect.

### Description of the Background

As display devices used for a monitor of a computer, a TV set, a mobile phone, and the like, there are an organic light-emitting display (OLED) configured to autonomously emit, and a liquid crystal display (LCD) that requires a separate light source.

The range of application of the display devices is diversified from the monitor of the computer and the TV set to personal mobile devices, and studies are being conducted on the display devices having wide display areas and having reduced volumes and weights.

In addition, recently, a display device including a light-emitting diode (LED) has attracted attention as a next-generation display device. Because the LED is made of an inorganic material instead of an organic material, the LED is more reliable and has a longer lifespan than a liquid crystal display device or an organic light-emitting display device. In addition, the LED may be quickly turned on or off, have excellent luminous efficiency, high impact resistance, and great stability, and display high-brightness images.

### SUMMARY

The present disclosure is to provide a display device capable of being subjected to self-alignment.

The present disclosure is also to provide a display device capable of minimizing a short-circuit defect.

The present disclosure is not limited to the above-mentioned, and other features, which are not mentioned above, may be clearly understood by those skilled in the art from the following descriptions.

A display device according to an aspect of the present disclosure includes a substrate on which a plurality of subpixels is defined, and a plurality of light-emitting elements respectively disposed in the plurality of subpixels, wherein each of the plurality of light-emitting elements includes a first semiconductor layer, a light-emitting layer on the first semiconductor layer, and a second semiconductor layer on the light-emitting layer, wherein the first semiconductor layer includes a first part having a flat top surface, and a second part protruding upward from the first part and being in direct contact with a bottom surface of the light-emitting layer, and wherein an area of a top surface of the second semiconductor layer is larger than an area of a bottom surface of the second semiconductor layer.

A display device according to another aspect of the present disclosure includes: a substrate on which a plurality of subpixels is defined; a plurality of light-emitting elements respectively disposed in the plurality of subpixels and each including a first semiconductor layer, a light-emitting layer on the first semiconductor layer, and a second semiconductor layer disposed on the light-emitting layer and configured such that an area of a top surface thereof is larger than an area of a bottom surface thereof; a first planarization layer disposed over the substrate to be equal to or higher than a top surface of the light-emitting layer and lower than a top surface of the second semiconductor layer; and a second planarization layer disposed on the first planarization layer and disposed at a height equal to a height of the top surface of the second semiconductor layer.

Other detailed matters of the exemplary aspects are included in the detailed description and the drawings.

According to the present disclosure, the light-emitting element has an omega shape, such that the first connection electrode may be disconnected from the top surface of the light-emitting element.

According to the present disclosure, the first planarization layer and the second planarization layer are disposed between the first connection electrode and the second connection electrode. In this case, the bottom surface of the second planarization layer is disposed to be higher than the top surface of the first semiconductor layer, which may suppress the contact between the first connection electrode and the second connection electrode and minimize a short-circuit defect.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic configuration view of a display device according to an aspect of the present disclosure;

FIG. 2 is a cross-sectional view of a subpixel of the display device according to the aspect of the present disclosure;

FIGS. 3A to 3C are process diagrams for explaining a method of manufacturing a light-emitting element of the display device according to the aspect of the present disclosure;

FIGS. 4A to 4D are process diagrams for explaining a self-assembling method of assembling the light-emitting element of the display device according to the aspect of the present disclosure;

FIGS. 5A to 5D are process diagrams for explaining a process of forming a first connection electrode and a second connection electrode of the display device according to the aspect of the present disclosure; and

FIG. 6 is a cross-sectional view of a display device according to another aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, various exemplary aspects of the present disclosure will be described in detail with reference to the accompanying drawings.

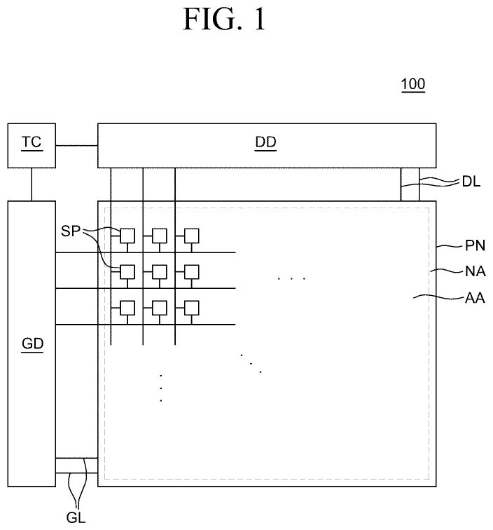

FIG. 1 is a schematic configuration view of a display device according to an aspect of the present disclosure. For convenience of description, FIG. 1 illustrates only a display panel PN, a gate drive part GD, a data drive part DD, and a timing controller TC among various constituent elements of a display device 100.

With reference to FIG. 1, the display device 100 includes the display panel PN including a plurality of subpixels SP, the gate drive part GD configured to supply various types of signals to the display panel PN, the timing controller TC configured to control the data drive part DD and the gate drive part GD, and the data drive part DD.

The gate drive part GD supplies a plurality of scan signals to a plurality of gate lines GL in response to a plurality of gate control signals provided from the timing controller TC. FIG. 1 illustrates that the single gate drive part GD is disposed to be spaced apart from one side of the display panel PN. However, the number and disposition of the gate drive part GD are not limited thereto.

The data drive part DD converts image data, which are inputted from the timing controller TC, into a data voltage by using a reference gamma voltage in response to a plurality of data control signals provided from the timing controller TC. The data drive part DD may supply the converted data voltage to a plurality of data lines DL.

The timing controller TC aligns image data, which are inputted from the outside, and supplies the image data to the data drive part DD. The timing controller TC may generate the gate control signals and the data control signals by using synchronizing signals, i.e., dot clock signals, data enable signals, and horizontal/vertical synchronizing signals inputted from the outside. Further, the timing controller TC may control the gate drive part GD and the data drive part DD by supplying the generated gate control signals and data control signals to the gate drive part GD and the data drive part DD.

The display panel PN is configured to display images to a user and includes the plurality of subpixels SP. In the display panel PN, the plurality of gate lines GL and the plurality of data lines DL intersect one another, and each of the plurality of subpixels SP is connected to the gate line GL and the data line DL. In addition, although not illustrated in the drawings, the plurality of subpixels SP may be respectively connected to a high-potential power line, a low-potential power line, a reference line, and the like.

The display panel PN may have a display area AA, and a non-display area NA configured to surround the display area AA.

The display area AA is an area of the display device 100 in which images are displayed. The display area AA may include a plurality of subpixels SP constituting a plurality of pixels, and a circuit configured to operate the plurality of subpixels SP. The plurality of subpixels SP is minimum units that constitute the display area AA. The n subpixels SP may constitute a single pixel PX. A light-emitting element 120, a thin-film transistor for operating the light-emitting element 120, and the like may be disposed in each of the plurality of subpixels SP. The plurality of light emitting elements 120 may be differently defined depending on the type of display panel PN. For example, in case that the display panel PN is an inorganic light-emitting display panel PN, the light-emitting element 120 may be a light-emitting diode (LED) or a micro light-emitting diode (micro LED).

A plurality of signal lines for transmitting various types of signals to the plurality of subpixels SP is disposed in the display area AA. For example, the plurality of signal lines may include the plurality of data lines DL for supplying data voltages to the plurality of subpixels SP, and the plurality of gate lines GL for supplying gate voltages to the plurality of subpixels SP. The plurality of gate lines GL may extend in one direction in the display area AA and be connected to the plurality of subpixels SP. The plurality of data lines DL may extend in a direction different from one direction in the display area AA and be connected to the plurality of subpixels SP. In addition, a low-potential power line, a high-potential power line, and the like may be further disposed in the display area AA. However, the present disclosure is not limited thereto.

The non-display area NA may be defined as an area in which no image is displayed, i.e., an area extending from the display area AA. The non-display area NA may include link lines and pad electrodes for transmitting signals to the subpixels SP in the display area AA. Alternatively, the non-display area NA may include drive ICs such as gate drivers IC and data drivers IC.

Meanwhile, the non-display area NA may be positioned on a rear surface of the display panel PN, i.e., a surface on which the subpixel SP is not present. Alternatively, the non-display area NA may be excluded. However, the present disclosure is not limited to the configuration illustrated in the drawings.

Meanwhile, the drive parts such as the gate drive part GD, the data drive part DD, and the timing controller TC may be connected to the display panel PN in various ways. For example, the gate drive part GD may be mounted in the non-display area NA by a gate-in-panel (GIP) method or mounted between the plurality of subpixels SP by a gate-in-active area (GIA) method in the display area AA. For example, the data drive part DD and the timing controller TC may be formed on a separate flexible film and a printed circuit board and electrically connected to the display panel PN by a method of bonding the flexible film and the printed circuit board to a pad electrode formed in the non-display area NA of the display panel PN. In case that the gate drive part GD is mounted by the GIP method and the data drive part DD and the timing controller TC transmit signals to the display panel PN through the pad electrode in the non-display area NA, it is necessary to ensure an area of the non-display area NA to dispose the gate drive part GD and the pad electrode, which may increase a bezel.

Alternatively, in case that the gate drive part GD is mounted in the display area AA by the GIA method and a side line SRL, which connects a signal line on a front surface of the display panel PN to the pad electrode on the rear surface of the display panel PN, is formed to bond the flexible film and the printed circuit board to the rear surface of the display panel PN, it is possible to minimize the non-display area NA on the front surface of the display panel PN. That is, in case that the gate drive part GD, the data drive part DD, and the timing controller TC are connected to the display panel PN by the above-mentioned method, a zero bezel in which the bezel is not substantially present may be implemented.

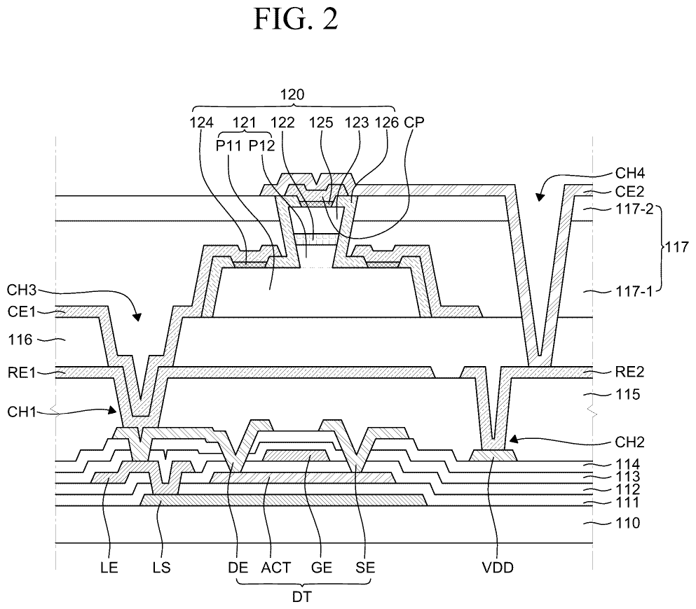

FIG. 2 is a cross-sectional view of the subpixel of the display device according to the aspect of the present disclosure. With reference to FIG. 2, the display panel PN of the display device 100 according to the aspect of the present disclosure includes a substrate 110, a buffer layer 111, a gate insulation layer 112, a first interlayer insulation layer 113, a second interlayer insulation layer 114, a passivation layer 115, a bonding layer 116, a planarization layer 117, a driving transistor DT, the light-emitting element 120, a first connection electrode CE1, a second connection electrode CE2, a light-blocking layer LS, and an auxiliary electrode LE.

With reference to FIG. 2, the substrate 110 is a component for supporting various constituent elements included in the display device 100 and may be made of an insulating material. For example, the substrate 110 may be made of glass, resin, or the like. In addition, the substrate 110 may be made of a material having polymer or plastic and also may be made of a material having flexibility.

The light-blocking layer LS is disposed on the substrate 110. The light-blocking layer LS blocks light entering an active layer ACT of the driving transistor DT, which will be described below, from a lower side of the substrate 110. The light-blocking layer LS may block light entering the active layer ACT of the driving transistor DT, thereby minimizing a leakage current.

The buffer layer 111 is disposed on the substrate 110 and the light-blocking layer LS. The buffer layer 111 may reduce the penetration of moisture or impurities through the substrate 110. For example, the buffer layer 111 may be configured as a single layer or multilayer made of silicon oxide (SiOx) or silicon nitride (SiNx). However, the present disclosure is not limited thereto. However, the buffer layer 111 may be excluded in accordance with the type of substrate 110 or the type of transistor. However, the present disclosure is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT may be made of a semiconductor material such as an oxide semiconductor, amorphous silicon, or polysilicon. However, the present disclosure is not limited thereto.

The gate insulation layer 112 is disposed on the active layer ACT. The gate insulation layer 112 is an insulation layer for insulating the active layer ACT and the gate electrode GE. The gate insulation layer 112 may be configured as a single layer or multilayer made of silicon oxide (SiOx) or silicon nitride (SiNx). However, the present disclosure is not limited thereto.

The gate electrode GE is disposed on the gate insulation layer 112. The gate electrode GE may be electrically connected to the source electrode SE of the driving transistor DT. The gate electrode GE may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The first interlayer insulation layer 113 and the second interlayer insulation layer 114 are disposed on the gate electrode GE. Contact holes, through which the source electrode SE and the drain electrode DE are connected to the active layer ACT, are formed in the first interlayer insulation layer 113 and the second interlayer insulation layer 114. The first interlayer insulation layer 113 and the second interlayer insulation layer 114 may be insulation layers for protecting components disposed below the first interlayer insulation layer 113 and components disposed below the second interlayer insulation layer 114 and each configured as a single layer or multilayer made of silicon oxide (SiOx) or silicon nitride (SiNx). However, the present disclosure is not limited thereto.

The source electrode SE and the drain electrode DE are disposed on the second interlayer insulation layer 114 and electrically connected to the active layer ACT. The source electrode SE and the drain electrode DE may each be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

Meanwhile, in the present disclosure, the configuration has been described in which the first interlayer insulation layer 113 and the second interlayer insulation layer 114, i.e., the plurality of insulation layers is disposed between the gate electrode GE, the source electrode SE, and the drain electrode DE. However, only a single insulation layer may be disposed between the gate electrode GE, the source electrode SE, and the drain electrode DE. However, the present disclosure is not limited thereto. However, as illustrated in the drawings, in case that the plurality of insulation layers, such as the first interlayer insulation layer 113 and the second interlayer insulation layer 114, is disposed between the gate electrode GE, the source electrode SE, and the drain electrode DE, an electrode may be additionally formed between the first interlayer insulation layer 113 and the second interlayer insulation layer 114. The additionally formed electrode may define a capacitor together with other components disposed below the first interlayer insulation layer 113 or disposed above the second interlayer insulation layer 114.

The auxiliary electrode LE is disposed on the gate insulation layer 112. The auxiliary electrode LE is an electrode that electrically connects the light-blocking layer LS, which is disposed below the buffer layer 111, to any one of the source electrode SE and the drain electrode DE on the second interlayer insulation layer 114. For example, the light-blocking layer LS may be electrically connected to any one of the source electrode SE or the drain electrode DE through the auxiliary electrode LE so as not to be operated as a floating gate, thereby minimizing a change in threshold voltage of the driving transistor DT caused by the floating light-blocking layer LS. The drawing illustrates that the light-blocking layer LS is connected to the drain electrode DE. However, the light-blocking layer LS may be connected to the source electrode SE. However, the present disclosure is not limited thereto.

A power line VDD is disposed on the second interlayer insulation layer 114. The power line VDD may be electrically connected to the light-emitting element 120 together with the driving transistor DT and allow the light-emitting element 120 to emit light. The power line VDD may be made of an electrically conductive material, for example, copper (Cu), aluminum (Al), molybdenum (Mo), nickel (Ni), titanium (Ti), chromium (Cr), or an alloy thereof. However, the present disclosure is not limited thereto.

The passivation layer 115 is disposed on the driving transistor DT and the power line VDD. The passivation layer 115 may be configured as a single layer or multilayer made of a photoresist, an acrylic-based organic material, or an inorganic material such as silicon oxide (SiOx) or silicon nitride (SiNx), for example. However, the present disclosure is not limited thereto.

The bonding layer 116 is disposed on the passivation layer 115. The front surface of the substrate 110 may be coated with the bonding layer 116, and the bonding layer 116 may fix the light-emitting element 120 disposed on the bonding layer 115. For example, the bonding layer 116 may be made of any one material selected from adhesive polymer, epoxy resist, UV resin, a polyimide-based material, an acrylate-based material, a urethane-based material, and polydimethylsiloxane (PDMS). However, the present disclosure is not limited thereto.

A first reflective electrode RE1 and a second reflective electrode RE2, which are spaced apart from each other, are disposed between the passivation layer 115 and a bonding layer 116. The first reflective electrode RE1 is a reflective plate that reflects light, which is emitted from the light-emitting element 120, toward an upper side of the light-emitting element 120 while electrically connecting the driving transistor DT and the first connection electrode CE1. The second reflective electrode RE2 is a reflective plate that reflects light, which is emitted from the light-emitting element 120, toward the upper side of the light-emitting element 120 while electrically connecting the power line VDD and the second connection electrode CE2. The first reflective electrode RE1 and the second reflective electrode RE2 may each be made of an electrically conductive material having excellent reflection performance and reflect the light, which is emitted from the light-emitting element 120, toward the upper side of the light-emitting element 120.

The first reflective electrode RE1 may be electrically connected to the drain electrode DE of the driving transistor DT through a first contact hole CH1 of the passivation layer 115. The second reflective electrode RE2 may be electrically connected to the power line VDD through a second contact hole CH2 of the passivation layer 115.

The light-emitting element 120 is disposed on the bonding layer 116 and overlaps the first reflective electrode RE1. The light-emitting elements 120 may be elements configured to emit light by using an electric current and include the light-emitting elements 120 configured to emit red light, green light, blue light, and the like. The light-emitting elements 120 may implement light with various colors including white by using a combination of red light, green light, blue light, and the like. For example, the light-emitting element 120 may be a light-emitting diode (LED) or a micro LED. However, the present disclosure is not limited thereto.

The light-emitting element 120 includes a first semiconductor layer 121, a light-emitting layer 122, a second semiconductor layer 123, a first electrode 124, a second electrode 125, and an encapsulation film 126. For example, the light-emitting element 120 is a light-emitting element having a lateral structure.

The first semiconductor layer 121 may be a semiconductor layer on which an electric current is generated as free electrons having negative charges move as carriers. The first semiconductor layer 121 may be a layer formed by doping a particular material with n-type impurities. For example, the first semiconductor layer 121 may be a layer formed by doping a material, such as gallium nitride (GaN), indium aluminum phosphide (InAlP), or gallium arsenic (GaAs), with n-type impurities. For example, the n-type impurity may be silicon (Si), germanium (Ge), tin (Sn), or the like. However, the present disclosure is not limited thereto. The light-emitting layer 122 may emit light by receiving positive holes and electrons from the first semiconductor layer 121 and the second semiconductor layer 123. The light-emitting layer 122 may be configured as a single layer or a multi-quantum well (MQW) structure. For example, the light-emitting layer 122 may be made of indium gallium nitride (InGaN), gallium nitride (GaN), or the like. However, the present disclosure is not limited thereto.

The second semiconductor layer 123 may be a semiconductor layer on which an electric current is generated as positive holes having positive charges move as carriers. The second semiconductor layer 123 may be a layer formed by doping a particular material with p-type impurities. For example, the second semiconductor layer 123 may be a layer formed by doping a material, such as gallium nitride (GaN), indium aluminum phosphide (InAlP), or gallium arsenic (GaAs), with p-type impurities. For example, the p-type impurity may be magnesium (Mg), zinc (Zn), beryllium (Be), or the like. However, the present disclosure is not limited thereto.

The first electrode 124 for forming ohmic contact is disposed on the first semiconductor layer 121. The first electrode 124 is an electrode that electrically connects the driving transistor DT and the first semiconductor layer 121. The first electrode 124 may be made of an electrically conductive material, for example, a transparent conductive material such as indium tin oxide (ITO) or indium zinc oxide (IZO) or an opaque conductive material such as titanium (Ti), gold (Au), silver (Ag), copper (Cu), or an alloy thereof. However, the present disclosure is not limited thereto.

The second electrode 125 for forming ohmic contact is disposed on the second semiconductor layer 123. The second electrode 125 is an electrode that electrically connects the second semiconductor layer 123 and the power line VDD. The second electrode 125 may be made of an electrically conductive material, e.g., a transparent conductive material such as indium tin oxide (ITO) or indium zinc oxide (IZO). However, the present disclosure is not limited thereto.

The encapsulation film 126 for protecting the first semiconductor layer 121 and the second semiconductor layer 123 is disposed on the first semiconductor layer 121 and the second semiconductor layer 123. The encapsulation film 126 may be made of SiO₂, Si₃N₄, or resin. The encapsulation film 126 may be disposed on a front surface of the light-emitting element 120, except for a lower portion of the light-emitting element 120. However, the first electrode 124 and the second electrode 125 are partially exposed by the encapsulation film 126. The first electrode 124 and the second electrode 125 are respectively in ohmic contact with the first connection electrode CE1 and the second connection electrode CE2 through the exposed area.

Meanwhile, the light-emitting element 120 has an omega (Ω) shape. Specifically, the first semiconductor layer 121 includes a first part p11 having a flat top surface, and a second part p12 protruding upward from the first part p11 and being in direct contact with a bottom surface of the light-emitting layer 122. An area of the top surface of the first part p11 is smaller than an area of a bottom surface of the first part p11, and an area of a top surface of the second part p12 is larger than an area of a bottom surface of the second part p12. That is, a cross-sectional shape of the first part p11 may be trapezoidal shape, a cross-sectional shape of the second part p12 may be an inverted trapezoidal shape. The light-emitting layer 122 is disposed on a top surface of the first semiconductor layer 121. An area of the top surface of the light-emitting layer 122 may be larger than an area of a bottom surface of the light-emitting layer 122. That is, a cross-sectional shape of the light-emitting layer 122 may be an inverted trapezoidal shape. The second semiconductor layer 123 is disposed on the top surface of the light-emitting layer 122. An area of a top surface of the second semiconductor layer 123 may be larger than an area of a bottom surface of the second semiconductor layer 123. That is, a cross-sectional shape of the second semiconductor layer 123 may be an inverted trapezoidal shape.

That is, the second semiconductor layer 123, the light-emitting layer 122, and the second part p12, which protrudes from the first part p11, has a smaller width than the top surface of the first part p11, and has an inverted trapezoidal cross-sectional shape, are disposed on the first part p11 of the first semiconductor layer 121 of the light-emitting element 120. Therefore, the light-emitting element 120 may have an omega shape, such that the first connection electrode CE1 may be connected only to the first semiconductor layer 121 and the first electrode 124. A more detailed description thereof will be described below.

Meanwhile, in the present disclosure, the configuration has been described in which the light-emitting element 120 includes the first semiconductor layer 121, the light-emitting layer 122, the second semiconductor layer 123, the first electrode 124, and the second electrode 125. The light-emitting element 120 may exclude the first electrode 124 or the like in accordance with design. However, the present disclosure is not limited thereto.

Next, the first connection electrode CE1 is disposed on the bonding layer 116. The first connection electrode CE1 is an electrode that electrically connects the light-emitting element 120 and the driving transistor DT. The first connection electrode CE1 may be electrically connected to the first reflective electrode RE1 through a third contact hole CH3 formed in the bonding layer 116, and the first connection electrode CE1 may be electrically connected to the drain electrode DE of the driving transistor DT through the first reflective electrode RE1. For example, the first connection electrode CE1 may be electrically connected to the top surface and the side surface of the first part p11 of the first semiconductor layer 121 and electrically connect the drain electrode DE of the driving transistor DT and the first electrode 124 and the first semiconductor layer 121 of the light-emitting element 120.

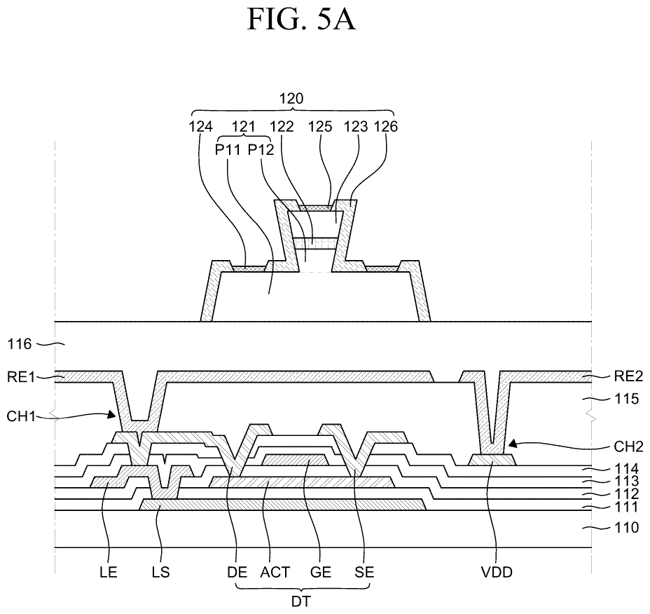

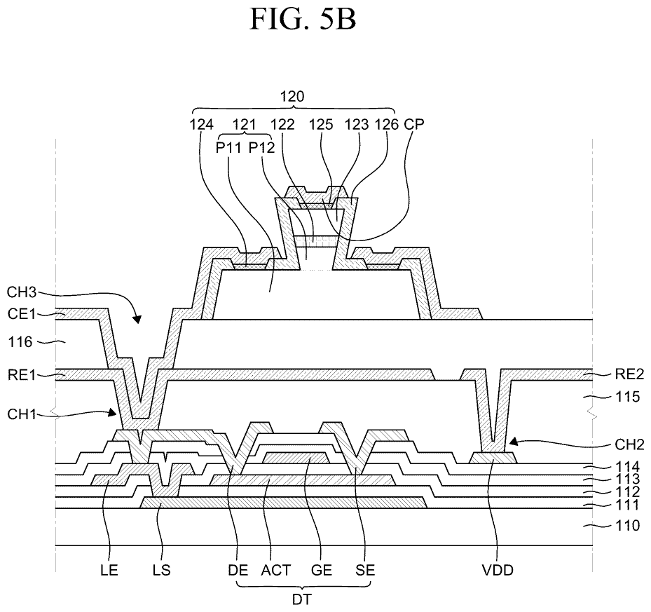

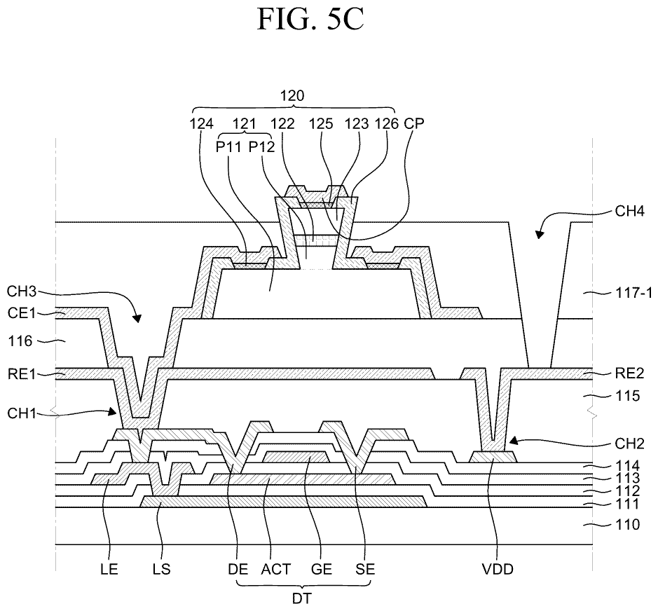

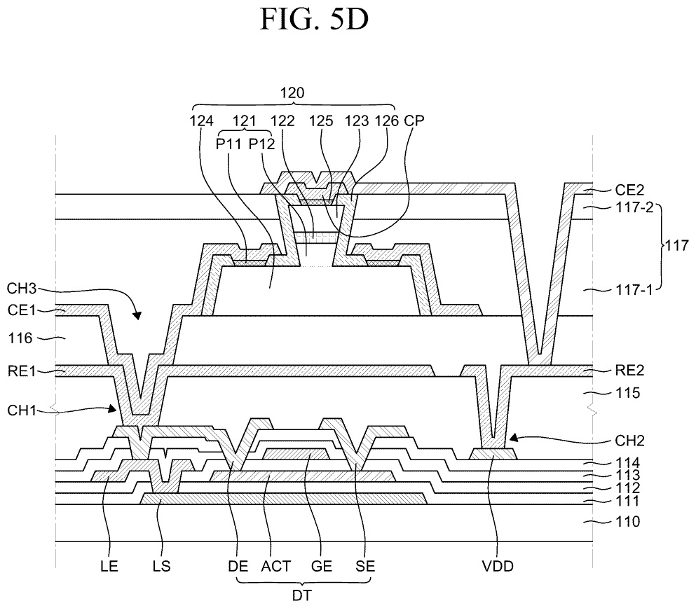

Meanwhile, a conductive pattern CP is disposed on the light-emitting element 120. The conductive pattern CP may be formed on an upper portion of the light-emitting element 120, i.e., formed on the second semiconductor layer 123 during a process of forming the first connection electrode CE1. For example, during the process of forming the first connection electrode CE1, a metallic material may not be deposited on the side surface of the light-emitting element 120 because of the light-emitting element 120 having an omega shape, and the first connection electrode CE1 and the conductive pattern CP may be formed to be separated from each other. The first connection electrode CE1 and the conductive pattern CP may be made of the same material. Therefore, during the process of forming the first connection electrode CE1, the conductive pattern CP may be formed at an upper side of the light-emitting element 120, and the conductive pattern CP may be disposed in a state of being disconnected from the first connection electrode CE1 by the light-emitting element 120 having an omega shape. A more detailed description thereof will be described below with reference to FIG. 5B.

The planarization layer 117 is disposed on the first connection electrode CE1 and the light-emitting element 120. The planarization layer 117 may planarize an upper portion of the substrate 110 on which the light-emitting element 120 is disposed. The planarization layer 117, together with the bonding layer 116, may fix the light-emitting element 120 onto the substrate 110. The planarization layer 117 may be made of a photoresist or an acrylic-based organic material. However, the present disclosure is not limited thereto.

For example, the planarization layer 117 may include a first planarization layer 117-1 configured to cover the first connection electrode CE1 and the light-emitting element 120, and a second planarization layer 117-2 on the first planarization layer 117-1.

The planarization layer 117 may be partially formed in an area of the substrate 110 that at least overlaps the light-emitting element 120 and the first connection electrode CE1. The planarization layer 117 is opened in an area that overlaps the power line VDD so that the second contact hole CH2 of the bonding layer 116 is exposed to the outside.

Meanwhile, the first planarization layer 117-1 may be formed to at least cover the first semiconductor layer 121 and the light-emitting layer 122 of the light-emitting element 120. A thickness of the first planarization layer 117-1 may be larger than a sum of a thickness of the first semiconductor layer 121 of the light-emitting element 120 and a thickness of the light-emitting layer 122. Further, the thickness of the first planarization layer 117-1 may be smaller than an overall thickness of the light-emitting element 120. For example, a top surface of the first planarization layer 117-1 may be disposed to be at a height at least higher than a height of the light-emitting layer 122 of the light-emitting element 120. The top surface of the first planarization layer 117-1 may be disposed to be at a height lower than a height of the top surface of the second semiconductor layer 123.

The second planarization layer 117-2 is disposed on the first planarization layer 117-1. The top surface of the second planarization layer 117-2 may be disposed to be at a height equal to or lower than a height of the top surface of the second semiconductor layer 123, and the bottom surface of the second planarization layer 117-2 may be disposed to be higher than the top surface of the first semiconductor layer 121. During the process of manufacturing the display device 100, only the second semiconductor layer 123 and the second electrode 125 may be exposed from the second planarization layer 117-2, and the second connection electrode CE2 may be electrically connected only to the second semiconductor layer 123 and the second electrode 125. A more detailed description thereof will be described below with reference to FIGS. 5A to 5D.

The second connection electrode CE2 is disposed on the planarization layer 117. The second connection electrode CE2 is an electrode that electrically connects the light-emitting element 120 and the power line VDD. The second connection electrode CE2 may be disposed to cover the upper portion of the light-emitting element 120 and electrically connected to the conductive pattern CP, and the second connection electrode CE2 may be electrically connected to the second electrode 125 and the second semiconductor layer 123 through the conductive pattern CP. In addition, the second connection electrode CE2 may be electrically connected to the second reflective electrode RE2 through a fourth contact hole CH4 and electrically connected to the power line VDD through the second reflective electrode RE2.

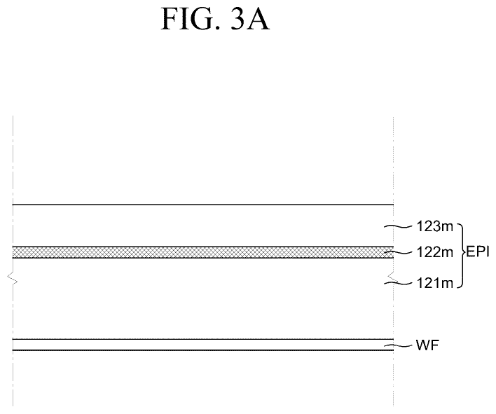

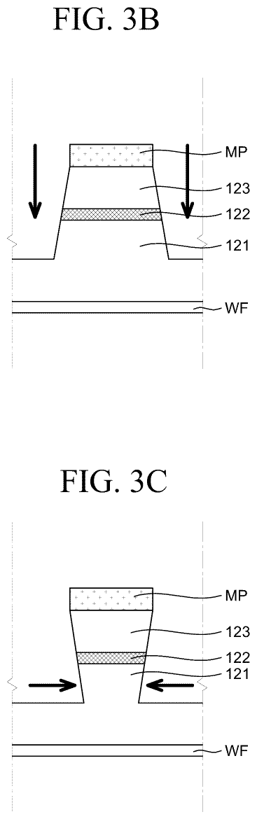

Hereinafter, a method of manufacturing the display device 100 according to the aspect of the present disclosure will be described with reference to FIGS. 3A to 5D.

FIGS. 3A to 3C are process diagrams for explaining a method of manufacturing the light-emitting element 120 of the display device according to the aspect of the present disclosure.

With reference to FIG. 3A, an epilayer EPI is grown on a wafer WF. The epilayer EPI may be a layer formed by growing materials that constitutes the first semiconductor layer 121, the light-emitting layer 122, and the second semiconductor layer 123 of the light-emitting element 120. The plurality of light-emitting elements 120 may be formed by patterning the plurality of epilayers EPI. For example, a first semiconductor material layer 121m, which constitutes the first semiconductor layer 121, a light-emitting material layer 122m, which constitutes the light-emitting layer 122, and a second semiconductor material layer 123m, which constitutes the second semiconductor layer 123, may be sequentially grown on the wafer WF.

Next, with reference to FIG. 3B, a mask pattern MP is formed on the epilayer EPI, and the epilayer EPI is etched. In this case, dry etching may be performed by using the mask pattern MP. In the dry etching, a horizontal etching speed and a vertical etching speed may be different from each other. In general, the vertical etching speed may be higher than the horizontal etching speed. Therefore, the dry etching may etch a portion, which does not overlap the mask pattern MP, in a depth direction while minimizing undercut made when a portion overlapping the mask pattern MP is etched.

Next, with reference to FIG. 3C, the light-emitting element 120 having an omega shape is formed by performing an additional etching process on the first semiconductor layer 121, the light-emitting layer 122, and the second semiconductor layer 123. The additional etching process may be used without limitation as long as an etching rate in a horizontal direction is higher than an etching rate in a vertical direction. For example, the light-emitting element 120 having an omega shape may be formed by performing a wet etching by using a material in which the etching rate in the horizontal direction is higher than the etching rate in the vertical direction. For example, tetra methyl ammonium hydroxide (TMAH) may be used as a material used for the wet etching. However, the present disclosure is not limited thereto. The TMAH is characterized in that a horizontal etching speed is higher than a vertical etching speed when the epilayer EPI is etched. Therefore, in the wet etching process using the TMAH, the etching may be more quickly performed in a direction of a side surface of the epilayer EPI than a depth direction of the epilayer EPI. The etching may be performed in a direction in which the widths of some of the plurality of first semiconductor layers 121, the plurality of light-emitting layers 122, and the plurality of second semiconductor layers 123 decrease. Therefore, the light-emitting element 120 having an omega shape may be formed by performing the wet etching using the TMAH.

Further, when the light-emitting element 120 having an omega shape is completely formed, the mask pattern MP may be removed, and the first electrode 124 and the second electrode 125 are formed, such that the light-emitting element 120 may be completely formed.

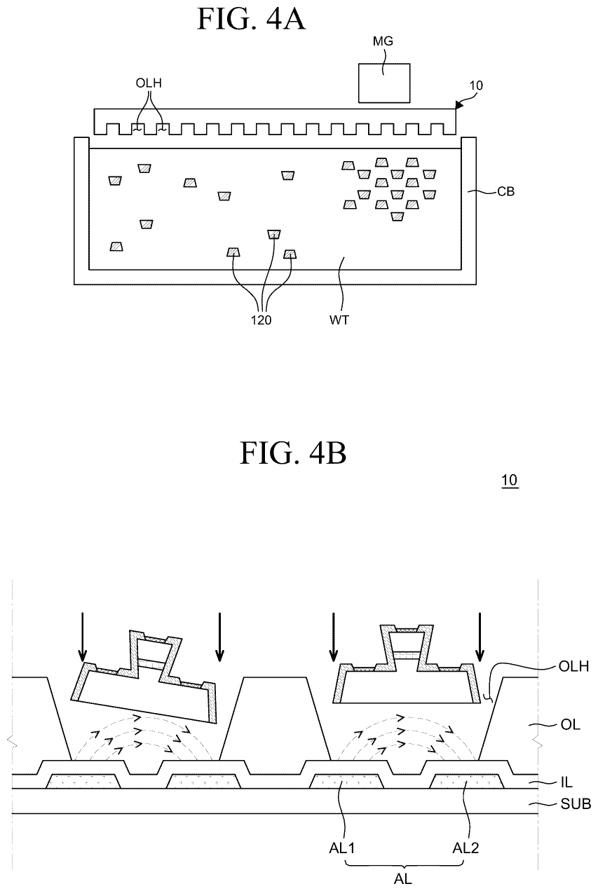

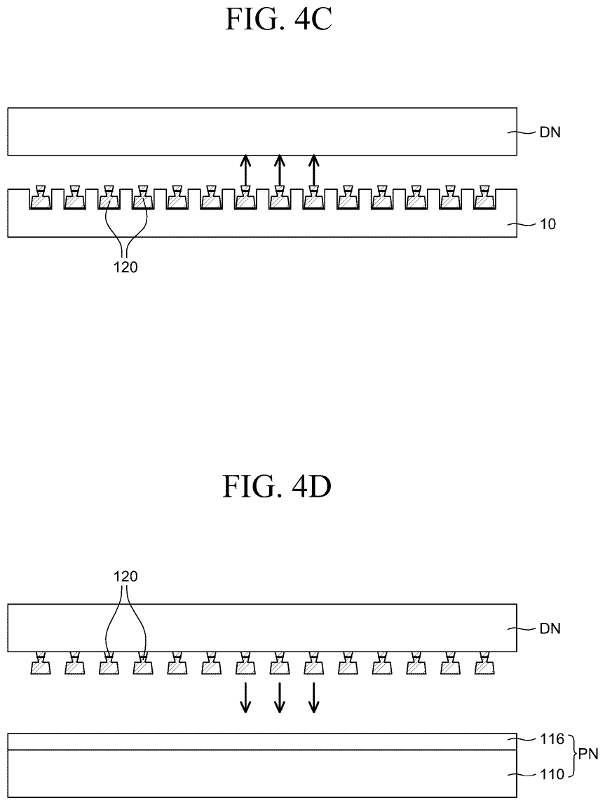

FIGS. 4A to 4D are process diagrams for explaining a self-assembling method of assembling the light-emitting element 120 of the display device according to the aspect of the present disclosure.

Next, with reference to FIG. 4A to 4D, the light-emitting element 120 may be transferred to the substrate 110 by the self-assembling method.

First, with reference to FIG. 4A, the light-emitting element 120 is inputted to a chamber CB filled with a fluid WT. The fluid WT may include water or the like, and the chamber CB filled with the fluid WT may have a shape opened at an upper side thereof.

Next, an assembling substrate 10 may be positioned on the chamber CB filled with the light-emitting element 120. The assembling substrate 10 is the substrate 110 on which the light-emitting element 120 is temporarily self-assembled. After the light-emitting element 120 is self-assembled on the assembling substrate 10, the light-emitting element 120 on the assembling substrate 10 may be transferred to the display device 100.

Next, a magnet MG may be positioned on the assembling substrate 10. The light-emitting elements 120, which are submerged or suspended on a bottom of the chamber CB, may be moved toward the assembling substrate 10 by a magnetic force of the magnet MG.

In this case, the light-emitting element 120 may include a magnetic element so that the light-emitting element 120 may be moved by a magnetic field. For example, any one of the first electrode 124 and the second electrode 125 of the light-emitting element 120 may include ferromagnetic materials such as iron or cobalt, such that a direction of the light-emitting element 120 directed toward the magnet MG may be aligned.

Next, the light-emitting element 120, which has been moved toward the assembling substrate 10 by the magnet MG, may be self-assembled to the assembling substrate 10 by an electric field formed by a plurality of assembling lines AL.

Specifically, with reference to FIG. 4B, the assembling substrate 10 includes an assembly substrate SUB, the plurality of assembling lines AL, an assembling insulation layer IL, and an organic layer OL.

First, the plurality of assembling lines AL is disposed on the assembly substrate SUB. The plurality of assembling lines AL includes a plurality of first assembling lines ALI and a plurality of second assembling lines AL2. The plurality of first assembling lines ALI and the plurality of second assembling lines AL2 may be disposed to be spaced apart from one another at predetermined intervals.

The assembling insulation layer IL is disposed on the plurality of assembling lines AL. The assembling insulation layer IL may protect the plurality of assembling lines AL from the fluid WT, thereby suppressing a defect such as corrosion of the plurality of assembling lines AL.

The organic layer OL including a plurality of pockets OLH is disposed on the assembling insulation layer IL. Each of the plurality of pockets OLH, which is formed by opening a part of the organic layer OL, may be an area in which the plurality of light-emitting elements 120 is self-assembled. The plurality of pockets OLH may be disposed to overlap an area between a pair of first and second assembling lines AL1 and AL2. Thereafter, the plurality of pockets OLH may each be formed at positions respectively corresponding to the plurality of subpixels SP of the display device 100. The plurality of pockets OLH may be disposed to respectively correspond to the plurality of subpixels SP in a one-to-one manner. The light-emitting elements 120 self-assembled in the plurality of pockets OLH may be transferred to the plurality of subpixels SP without change.

Further, the plurality of light-emitting elements 120 may be self-assembled in the pockets OLH of the organic layer OL by applying voltages to the plurality of assembling lines AL. For example, an electric field may be formed by applying alternating current voltages to the plurality of first assembling lines ALI and the plurality of second assembling lines AL2. The light-emitting element 120 may have a polarity by being dielectrically polarized by the electric field. Further, the dielectrically polarized light-emitting element 120 may be fixed or moved in a particular direction by dielectrophoresis (DEP), i.e., the electric field. Therefore, the plurality of light-emitting elements 120 may be temporarily self-assembled inside the pockets OLH of the assembling substrate 10 by using the dielectrophoresis.

In this case, the light-emitting element 120 may be self-assembled in the pocket OLH so that the first semiconductor layer 121 further extends downward than the second semiconductor layer 123. That is, the light-emitting element 120 may be self-assembled in an omega shape in the pocket OLH.

Next, with reference to FIG. 4C, the plurality of light-emitting elements 120 of the assembling substrate 10 is transferred to a donor DN.

First, the assembling substrate 10 and the donor DN are aligned so that the plurality of light-emitting elements 120 and the donor DN face one another. Further, the assembling substrate 10 and the donor DN may be joined, such that an upper portion of the light-emitting element 120 may be in contact with the donor DN. In this case, the donor DN is made of a material having an adhesive force, such that the upper portions of the plurality of light-emitting elements 120 may be bonded to the donor DN and transferred to the donor DN from the assembling substrate 10. The donor DN may be made of a polymer material having viscoelasticity, e.g., polydimethylsiloxane (PDMS), polyurethane acrylate (PUA), polyethylene glycol (PEG), polymethylmethacrylate (PMMA), polystyrene (PS), epoxy resin, urethane resin, acrylic resin, or the like. However, the present disclosure is not limited thereto.

Next, with reference to FIG. 4D, the plurality of light-emitting elements 120 on the donor DN is transferred onto the bonding layer 116 of the display device 100.

The donor DN and the display device 100 formed with the bonding layer 116 are aligned. The display device 100 and the donor DN may be aligned so that the plurality of light-emitting elements 120 of the donor DN and the bonding layer 116 of the display device 100 face one another. Further, the donor DN and the display device 100 may be joined, such that the light-emitting element 120 on the donor DN may be transferred onto the bonding layer 116.

In this case, a bonding force between the bonding layer 116 and the light-emitting element 120 is higher than a bonding force between the donor DN and the light-emitting element 120, such that the light-emitting element 120 may be detached from the donor DN and attached to the bonding layer 116.

Therefore, the light-emitting elements 120 each having an omega shape may be formed on the wafer WF, the light-emitting elements 120 may be self-assembled to be disposed on the assembling substrate 10 while corresponding to the plurality of subpixels SP, and then the plurality of light-emitting elements 120 on the assembling substrate 10 may be transferred to the display device 100 by using the donor DN. In this case, it is possible to omit the process of transferring the plurality of light-emitting elements 120 to the donor DN from the wafer WF after aligning the plurality of light-emitting elements 120 so that the plurality of light-emitting elements 120 corresponds to the intervals between the plurality of subpixels SP. The light-emitting element 120 may be easily self-assembled at an exact position by using an electric field. Therefore, the plurality of light-emitting elements 120 on the wafer WF is self-assembled by using the assembling substrate 10, which may minimize an alignment error and simplify the process of transferring the plurality of light-emitting elements 120.

In the present disclosure, the configuration has been described in which the plurality of light-emitting elements 120 is self-assembled to the assembling substrate 10 by the self-assembling method and then transferred to the display device 100 by using the donor DN. However, the present disclosure is not limited thereto. For example, the plurality of light-emitting elements 120 may be transferred directly to the donor DN from the wafer WF and transferred to the display device 100 without the self-assembling method. The plurality of light-emitting elements 120 may be self-assembled directly to the display device 100 by forming a separate assembling line AL in the display device 100. However, the present disclosure is not limited thereto.

FIGS. 5A to 5D are process diagrams for explaining a method of manufacturing the display device 100 according to the aspect of the present disclosure.

With reference to FIGS. 5A to 5D, the light-emitting element 120 is transferred onto the bonding layer 116 of the display device 100, and then the first connection electrode CE1 and the second connection electrode CE2 are formed, such that the light-emitting element 120 may be electrically connected to the driving transistor DT and the power line VDD.

First, with reference to FIG. 5A, the first contact hole CH1 and the second contact hole CH2 formed in the passivation layer 115 through a mask process. For example, the first contact hole CH1, which exposes the drain electrode DE, and the second contact hole CH2, which overlaps the power line VDD, may be formed in the passivation layer 115.

Next, the first reflective electrode RE1 and the second reflective electrode RE2 are formed on the passivation layer 115, and the bonding layer 116 is formed on the first reflective electrode RE1 and the second reflective electrode RE2.

Further, the light-emitting element 120 may be transferred onto the bonding layer 116 through the transfer process described with reference to FIGS. 4A to 4D.

Next, with reference to FIG. 5B, the third contact hole CH3 is formed by removing a part of the bonding layer 116 to overlap the first contact hole CH1 to electrically connect the first connection electrode CE1 and the drain electrode DE of the driving transistor DT to be formed later. The first reflective electrode RE1 connected to the drain electrode DE of the driving transistor DT may be exposed through the third contact hole CH3.

Thereafter, a conductive material layer, which covers the bonding layer 116 and the light-emitting element 120, is formed and patterned. The conductive material layer may be formed to cover the light-emitting element 120 and an area adjacent to the light-emitting element 120. For example, the conductive material layer may be formed to cover the upper portion of the light-emitting element 120 and a top surface of the bonding layer 116 adjacent to the light-emitting element 120. Further, the conductive material layer may be formed to cover the area in which the third contact hole CH3 is formed. Therefore, a part of the conductive material layer, which is disposed on the bonding layer 116 and connects the third contact hole CH3 and the first semiconductor layer 121 of the light-emitting element 120, may be the first connection electrode CE1.

In this case, the conductive material layer may be made of a metallic material having low step coverage and disconnected at a position in the vicinity of an upper edge of the light-emitting element 120 without covering the entire side surface of the light-emitting element 120 having an omega shape. Further, the conductive pattern CP of the conductive material layer, which covers the upper portion of the light-emitting element 120, is disconnected from the first connection electrode CE1 disposed on the top surface of the bonding layer 116 by the light-emitting element 120 having an omega shape and only serves as an electrode layer that merely covers the upper portion of the light-emitting element 120.

For example, the conductive material layer may be deposited by a physical vapor deposition (PVD) method. In case that the physical vapor deposition method is used, the metallic material may be deposited on the substrate 110 while moving rectilinearly from a target material. However, the metallic material, which is to move toward the side surface of the light-emitting element 120, is covered by the upper portion of the light-emitting element 120, such that the metallic material may not move toward the side surface of the light-emitting element 120, and the deposition on the side surface of the light-emitting element 120 may be hindered. Therefore, the metallic material may not be normally deposited on the side surface of the light-emitting element 120 having an omega shape, and the metallic materials formed around the upper and lower portions of the light-emitting element 120 may be disconnected from each other and divided into the first connection electrode CE1 and the conductive pattern CP.

Therefore, the conductive material layer is formed to cover the light-emitting element 120 and a part of the bonding layer 116 having the third contact hole CH3, such that the first connection electrode CE1, which electrically connects the first semiconductor layer 121 of the light-emitting element 120 and the driving transistor DT, may be formed in a self-alignment manner. Further, the conductive pattern CP, which covers the upper portion of the light-emitting element 120, is formed together with the first connection electrode CE1, but the conductive pattern CP is disconnected from the first connection electrode CE1 by the light-emitting element 120 having an omega shape. Therefore, it is possible to suppress a short-circuit defect of the first semiconductor layer 121 and the second semiconductor layer 123.

Next, with reference to FIG. 5C, the first planarization layer 117-1 is formed to cover the light-emitting element 120 and the first connection electrode CE1. The first planarization layer 117-1 may be disposed in an area that overlaps the light-emitting element 120 and the first connection electrode CE1. The first planarization layer 117-1 may be disposed to cover the first semiconductor layer 121 and the light-emitting layer 122 of the light-emitting element 120. A part of the bonding layer 116 which overlaps the second reflective electrode RE2 and the second semiconductor layer 123 and the second electrode 125 of the light-emitting element 120 may be exposed from the first planarization layer 117-1. The first planarization layer 117-1 may be disposed to cover the first connection electrode CE1, the first semiconductor layer 121, and the light-emitting layer 122, thereby suppressing a short-circuit defect of the second connection electrode CE2.

Meanwhile, an ashing process may be performed to adjust a thickness of the first planarization layer 117-1. For example, the ashing process, which decreases an overall thickness of a first planarization material layer is performed after the first planarization material layer is formed on the front surface of the substrate 110, such that a thickness of the first planarization layer 117-1 may be set to a thickness between an overall thickness of the light-emitting element 120 and a sum of a thickness of the first semiconductor layer 121 and a thickness of the light-emitting layer 122. However, the present disclosure is not limited thereto.

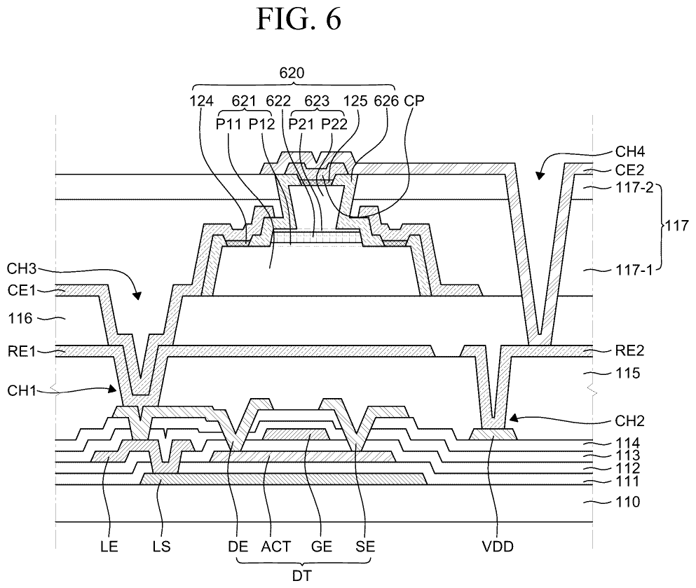

With reference to FIG. 6, the second planarization layer 117-2 is formed on the first planarization layer 117-1, and the fourth contact hole CH4 is formed so that the second reflective electrode RE2 connected to the power line VDD is exposed.

The second connection electrode CE2 is formed on the second planarization layer 117-2 and the light-emitting element 120. The second connection electrode CE2, which electrically connects the power line VDD and the upper portion of the light-emitting element 120 exposed from the second planarization layer 117-2, may be formed by forming an electrically conductive material layer on the front surface of the substrate 110. The second connection electrode CE2 may be electrically connected to the second electrode 125 and the second semiconductor layer 123 while adjoining the conductive pattern CP and electrically connected to the power line VDD through the fourth contact hole CH4.

Meanwhile, an ashing process may be performed to adjust a thickness of the second planarization layer 117-2. For example, the ashing process, which decreases an overall thickness of a second planarization material layer, is performed after the second planarization material layer is formed on the front surface of the substrate 110, such that a thickness of the second planarization layer 117-2 may be set to a thickness higher than the top surface of the first semiconductor layer 121 and equal to or lower than the top surface of the second semiconductor layer 123. However, the present disclosure is not limited thereto.

According to the aspectaspect of the present disclosure, because of the light-emitting element 120 having an omega shape, the first connection electrode CE1 may not cover the entire side surface of the light-emitting element 120, i. e., the side surface of the second part p12 of the first semiconductor layer 121. In addition, because the first planarization layer 117-1 is formed to cover the first semiconductor layer 121 and the light-emitting layer 122 of the light-emitting element 120, a short-circuit defect of the first connection electrode CE1 and the second connection electrode CE2 may be suppressed even though the second planarization layer 117-2 is over-etched during the process of performing the ashing process on the second planarization layer 117-2 to be formed on the first planarization layer 117-1 later.

Meanwhile, in the present disclosure, the configuration has been described in which the second connection electrode CE2 is formed in the state in which the conductive pattern CP is present to cover the upper side of the light-emitting element 120. However, the conductive pattern CP may be removed during an intermediate process, such that the second connection electrode CE2 may directly adjoin the second electrode 125.

Therefore, in the display device 100 and the method of manufacturing the display device 100 according to the aspectaspect of the present disclosure, the first connection electrode CE1 may be formed in a self-alignment manner and electrically connected to the first semiconductor layer 121 of the light-emitting element 120. Specifically, first, a conductive material layer may be formed to cover the light-emitting element 120. In this case, because the light-emitting element 120 has an omega shape, the conductive material layer may be disconnected without being formed to cover the entire side surface of the light-emitting element 120 having an omega shape. Therefore, the conductive pattern CP formed on the upper portion of the light-emitting element 120 may be disconnected from the first connection electrode CE1 that surrounds the first part p11 of the first semiconductor layer 121. The first connection electrode CE1 may electrically connect only the driving transistor DT and the first semiconductor layer 121. Therefore, at the time of forming the conductive material layer on the substrate 110, the first connection electrode CE1 may be formed without a separate alignment process, such that the process of forming the first connection electrode CE1 may be simplified.

In addition, in the display device 100 and the method of manufacturing the display device 100 according to the aspectaspect of the present disclosure, the second connection electrode CE2 may be formed in a self-alignment manner and electrically connected to the second semiconductor layer 123 of the light-emitting element 120. After the first connection electrode CE1 is formed, the first planarization layer 117-1, which covers the first semiconductor layer 121 and the light-emitting layer 122 of the light-emitting element 120 and the first connection electrode CE1, may be formed, and the second planarization layer 117-2 may be formed on the first planarization layer 117-1. In this case, even though the second connection electrode CE2 is formed on the front surface of the substrate 110, the second connection electrode CE2 may be separated from the first connection electrode CE1 and the first semiconductor layer 121 by the first planarization layer 117-1 and the second planarization layer 117-2. Therefore, it is possible to suppress a short-circuit defect of the second connection electrode CE2. Therefore, the second connection electrode CE2 may be formed in a self-alignment manner by forming the electrically conductive material layer on the front surface of the substrate 110 without precisely aligning a position at which the first connection electrode CE1 is formed and a position at which the light-emitting element 120 is formed. Therefore, it is possible to simplify the process of manufacturing the display device 100.

In addition, according to the display device 100 and the method of manufacturing the display device 100 according to the aspectaspect of the present disclosure, the first connection electrode CE1 and the second connection electrode CE2 are formed in a self-alignment manner, which may reduce a short-circuit defect caused by an alignment position error and ensure a transfer margin.

FIG. 6 is a cross-sectional view of a display device according to another aspectaspect of the present disclosure. A display device 600 in FIG. 6 is substantially identical in configuration to the display device 100 in FIGS. 1 to 5D, except for a shape of a light-emitting element 620. Therefore, a repeated description will be omitted.

With reference to FIG. 6, the light-emitting element 620 includes a first semiconductor layer 621, a light-emitting layer 622, a second semiconductor layer 623, the first electrode 124, the second electrode 125, and an encapsulation film 626 and has an omega ( ) shape.

Specifically, the first semiconductor layer 621 includes a first part p11 having a flat top surface, and a second part p12 protruding upward from the first part p11 and being in direct contact with a bottom surface of the light-emitting layer 622. In this case, an area of the top surface of the first part p11 may be smaller than an area of a bottom surface of the first part p11, and an area of a top surface of the second part p12 may be smaller than an area of a bottom surface of the second part p12. That is, a cross-sectional shape of each of the first part p11 and the second part p12 of the first semiconductor layer 621 may be a trapezoidal shape.

The light-emitting layer 622 is disposed on a top surface of the first semiconductor layer 621. An area of the top surface of the light-emitting layer 622 may be smaller than an area of a bottom surface of the light-emitting layer 622. That is, a cross-sectional shape of the light-emitting layer 622 may be a trapezoidal shape.

The second semiconductor layer 623 is disposed on the top surface of the light-emitting layer 622. The second semiconductor layer 623 includes a first part p21 having a flat top surface, and a second part p22 protruding upward from the first part p21. An area of a top surface of the first part p21 of the second semiconductor layer 623 is smaller than an area of a bottom surface of the first part p21 of the second semiconductor layer 623, and an area of a top surface of the second part p22 of the second semiconductor layer 623 is larger than an area of a bottom surface of the second part p22 of the second semiconductor layer 623. That is, a cross-sectional shape of the first part p21 of the second semiconductor layer 623 may be a trapezoidal shape, and a cross-sectional shape of the second part p22 of the second semiconductor layer 623 may be an inverted trapezoidal shape.

According to the aspectaspect of the present disclosure, the second semiconductor layer 623 having a generally inverted trapezoidal cross-sectional shape is disposed on the top surface of the light-emitting layer 622, such that the light-emitting element 620 may have an omega shape. Therefore, the first connection electrode CE1 may be disposed to surround a top surface and a side surface of the first part p11 of the first semiconductor layer 621, a side surface of the second part p12 of the first semiconductor layer 621, and a side surface of the light-emitting layer 622. The conductive pattern CP may be formed on an upper portion of the light-emitting emitting element 620, i. e., the top surface of the second semiconductor layer 623 with the first connection electrode CE1.

In addition, the first planarization layer 117-1 is disposed to be equal to or higher than the top surface of the light-emitting layer 622 and lower than the top surface of the second semiconductor layer 623, and the second planarization layer 117-2, which is disposed at the same height as the top surface of the second semiconductor layer 623, is positioned on the first planarization layer 117-1. Therefore, the second connection electrode CE2 is just electrically connected to the conductive pattern CP, which covers the upper portion of the second semiconductor layer 623, and disconnected from the first connection electrode CE1 when the second connection electrode CE2 is formed later. Therefore, it is possible to minimize a short-circuit defect between the first connection electrode CE1 and the second connection electrode CE2.

In addition, the first semiconductor layer 621 and the light-emitting layer 622 may be formed to have a trapezoidal cross-sectional shape, such that the light-emitting layer 622 occupies a larger area, which may further improve the luminous efficiency.

The exemplary aspects of the present disclosure may also be described as follows:

According to an aspect of the present disclosure, a display device comprises a substrate on which a plurality of subpixels is defined, and a plurality of light-emitting elements respectively disposed in the plurality of subpixels, wherein each of the plurality of light-emitting elements comprises a first semiconductor layer, a light-emitting layer on the first semiconductor layer, and a second semiconductor layer on the light-emitting layer, wherein the first semiconductor layer comprises a first part having a flat top surface, and a second part protruding upward from the first part and being in direct contact with a bottom surface of the light-emitting layer, and wherein an area of a top surface of the second semiconductor layer is larger than an area of a bottom surface of the second semiconductor layer.

An area of a top surface of the first part of the first semiconductor layer may be smaller than an area of a bottom surface of the first part of the first semiconductor layer, an area of a top surface of the second part of the first semiconductor layer may be larger than an area of a bottom surface of the second part of the first semiconductor layer, and an area of a top surface of the light-emitting layer may be larger than an area of a bottom surface of the light-emitting layer.

A cross-sectional shape of each of the second part of the first semiconductor layer, the light-emitting layer, and the second semiconductor layer may be an inverted trapezoidal shape.

The area of the top surface of the first part of the first semiconductor layer may be smaller than the area of the bottom surface of the first part of the first semiconductor layer, the area of the top surface of the second part of the first semiconductor layer may be smaller than the area of the bottom surface of the second part of the first semiconductor layer, and the area of the top surface of the light-emitting layer may be smaller than the area of the bottom surface of the light-emitting layer.

The second semiconductor layer comprises a first part having a flat top surface, and a second part protruding upward from the first part, an area of a top surface of the first part of the second semiconductor layer may be smaller than an area of a bottom surface of the first part of the second semiconductor layer, and an area of a top surface of the second part of the second semiconductor layer may be larger than an area of a bottom surface of the second part of the second semiconductor layer.

A cross-sectional shape of the second part of the second semiconductor layer may be an inverted trapezoidal shape.

The display device may further comprise a first connection electrode electrically connected to the top surface of the first part of the first semiconductor layer, a conductive pattern disposed over the second semiconductor layer, and a second connection electrode disposed on the conductive pattern and electrically connected to the second semiconductor layer.

The first connection electrode and the conductive pattern may be made of the same material.

The display device may further comprise a planarization layer disposed between the first connection electrode and the second connection electrode, the planarization layer comprises a first planarization layer on the first connection electrode, and a second planarization layer on the first planarization layer, a top surface of the second planarization layer may be disposed at a height equal to or lower than a height of a top surface of the second semiconductor layer, and a bottom surface of the second planarization layer may be disposed to be higher than a top surface of the first semiconductor layer.

The display device may further comprise a bonding layer disposed below the light-emitting element and the first connection electrode, a driving transistor disposed between the substrate and the bonding layer, and a power line disposed between the substrate and the bonding layer, wherein the first connection electrode electrically connects the driving transistor and the first semiconductor layer through a contact hole of the bonding layer, and wherein the second connection electrode may electrically connect the power line and the second semiconductor layer through a contact hole of the bonding layer.

According to another aspect of the present disclosure, a display device comprises a substrate on which a plurality of subpixels is defined; a plurality of light-emitting elements respectively disposed in the plurality of subpixels and each comprising a first semiconductor layer, a light-emitting layer on the first semiconductor layer, and a second semiconductor layer disposed on the light-emitting layer and configured such that an area of a top surface thereof is larger than an area of a bottom surface thereof; a first planarization layer disposed over the substrate to be equal to or higher than a top surface of the light-emitting layer and lower than a top surface of the second semiconductor layer; and a second planarization layer disposed on the first planarization layer and disposed at a height equal to a height of the top surface of the second semiconductor layer.

The first semiconductor layer comprises a first part having a flat top surface, and a second part protruding upward from the first part and being in direct contact with a bottom surface of the light-emitting layer, an area of a top surface of the first part of the first semiconductor layer may be smaller than an area of a bottom surface of the first part of the first semiconductor layer, an area of a top surface of the second part of the first semiconductor layer may be larger than an area of a bottom surface of the second part of the first semiconductor layer, and an area of a top surface of the light-emitting layer may be larger than an area of a bottom surface of the light-emitting layer.

The area of the top surface of the first part of the first semiconductor layer may be smaller than the area of the bottom surface of the first part of the first semiconductor layer, the area of the top surface of the second part of the first semiconductor layer may be smaller than the area of the bottom surface of the second part of the first semiconductor layer, and the area of the top surface of the light-emitting layer may be smaller than the area of the bottom surface of the light-emitting layer.

The second semiconductor layer comprises a first part having a flat top surface, and a second part protruding upward from the first part, an area of a top surface of the first part of the second semiconductor layer may be smaller than an area of a bottom surface of the first part of the second semiconductor layer, and an area of a top surface of the second part of the second semiconductor layer may be larger than an area of a bottom surface of the second part of the second semiconductor layer.

The display device may further comprise a first connection electrode electrically connected to the top surface of the first part of the first semiconductor layer, a conductive pattern disposed over the second semiconductor layer, and a second connection electrode disposed on the conductive pattern and electrically connected to the second semiconductor layer.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a substrate on which a plurality of subpixels is defined; and
a plurality of light-emitting elements respectively disposed in the plurality of subpixels,
wherein each of the plurality of light-emitting elements comprises a first semiconductor layer, a light-emitting layer on the first semiconductor layer, and a second semiconductor layer on the light-emitting layer,
wherein the first semiconductor layer comprises a first part having a flat top surface, and a second part protruding upward from the first part and being in direct contact with a bottom surface of the light-emitting layer, and
wherein an area of a top surface of the second semiconductor layer is larger than an area of a bottom surface of the second semiconductor layer.

2. The display device of claim 1, wherein an area of a top surface of the first part of the first semiconductor layer is smaller than an area of a bottom surface of the first part of the first semiconductor layer, an area of a top surface of the second part of the first semiconductor layer is larger than an area of a bottom surface of the second part of the first semiconductor layer, and an area of a top surface of the light-emitting layer is larger than an area of a bottom surface of the light-emitting layer.

3. The display device of claim 2, wherein a cross-sectional shape of each of the second part of the first semiconductor layer, the light-emitting layer, and the second semiconductor layer is an inverted trapezoidal shape.

4. The display device of claim 1, wherein an area of a top surface of the first part of the first semiconductor layer is smaller than an area of a bottom surface of the first part of the first semiconductor layer, an area of a top surface of the second part of the first semiconductor layer is smaller than an area of a bottom surface of the second part of the first semiconductor layer, and an area of a top surface of the light-emitting layer is smaller than an area of a bottom surface of the light-emitting layer.

5. The display device of claim 4, wherein the second semiconductor layer comprises a first part having a flat top surface, and a second part protruding upward from the first part, an area of a top surface of the first part of the second semiconductor layer is smaller than an area of a bottom surface of the first part of the second semiconductor layer, and an area of a top surface of the second part of the second semiconductor layer is larger than an area of a bottom surface of the second part of the second semiconductor layer.

6. The display device of claim 5, wherein a cross-sectional shape of the second part of the second semiconductor layer is an inverted trapezoidal shape.

7. The display device of claim 2, further comprising:
a first connection electrode electrically connected to the top surface of the first part of the first semiconductor layer;
a conductive pattern disposed over the second semiconductor layer; and
a second connection electrode disposed on the conductive pattern and electrically connected to the second semiconductor layer.

8. The display device of claim 7, wherein the first connection electrode and the conductive pattern are made of the same material.

9. The display device of claim 7, further comprising a planarization layer disposed between the first connection electrode and the second connection electrode,
wherein the planarization layer comprises:
a first planarization layer on the first connection electrode; and
a second planarization layer on the first planarization layer,
wherein a top surface of the second planarization layer is disposed at a height equal to or lower than a height of a top surface of the second semiconductor layer, and
wherein a bottom surface of the second planarization layer is disposed to be higher than a top surface of the first semiconductor layer.

10. The display device of claim 7, further comprising:
a bonding layer disposed below the light-emitting element and the first connection electrode;
a driving transistor disposed between the substrate and the bonding layer; and
a power line disposed between the substrate and the bonding layer,
wherein the first connection electrode electrically connects the driving transistor and the first semiconductor layer through a first contact hole of the bonding layer, and
wherein the second connection electrode electrically connects the power line and the second semiconductor layer through a second contact hole of the bonding layer.

11. A display device comprising:
a substrate on which a plurality of subpixels is defined;
a plurality of light-emitting elements respectively disposed in the plurality of subpixels and each comprising a first semiconductor layer, a light-emitting layer on the first semiconductor layer, and a second semiconductor layer disposed on the light-emitting layer and configured such that an area of a top surface thereof is larger than an area of a bottom surface thereof;
a first planarization layer disposed over the substrate so as to be equal to or higher than a top surface of the light-emitting layer and lower than a top surface of the second semiconductor layer; and
a second planarization layer disposed on the first planarization layer and disposed at a height equal to a height of the top surface of the second semiconductor layer.

12. The display device of claim 11, wherein the first semiconductor layer comprises a first part having a flat top surface, and a second part protruding upward from the first part and being in direct contact with a bottom surface of the light-emitting layer, an area of a top surface of the first part of the first semiconductor layer is smaller than an area of a bottom surface of the first part of the first semiconductor layer, an area of a top surface of the second part of the first semiconductor layer is larger than an area of a bottom surface of the second part of the first semiconductor layer, and an area of a top surface of the light-emitting layer is larger than an area of a bottom surface of the light-emitting layer.

13. The display device of claim 11, wherein the first semiconductor layer comprises a first part having a flat top surface, and a second part protruding upward from the first part and being in direct contact with a bottom surface of the light-emitting layer,
wherein an area of a top surface of the first part of the first semiconductor layer is smaller than an area of a bottom surface of the first part of the first semiconductor layer, an area of a top surface of the second part of the first semiconductor layer is smaller than an area of a bottom surface of the second part of the first semiconductor layer, and
wherein an area of a top surface of the light-emitting layer is smaller than an area of a bottom surface of the light-emitting layer.

14. The display device of claim 13, wherein the second semiconductor layer comprises a first part having a flat top surface, and a second part protruding upward from the first part, an area of a top surface of the first part of the second semiconductor layer is smaller than an area of a bottom surface of the first part of the second semiconductor layer, and
wherein an area of a top surface of the second part of the second semiconductor layer is larger than an area of a bottom surface of the second part of the second semiconductor layer.

15. The display device of claim 12, further comprising:
a first connection electrode electrically connected to the top surface of the first part of the first semiconductor layer;
a conductive pattern disposed over the second semiconductor layer; and
a second connection electrode disposed on the conductive pattern and electrically connected to the second semiconductor layer.

16. The display device of claim 15, wherein the first connection electrode and the conductive pattern are made of the same material.

17. The display device of claim 16, wherein the material is deposited toward the light-emitting element and disconnected at a side surface of the light-emitting element, so as to simultaneously form the first connection electrode and the conductive pattern.
